(19) United States
(12) Patent Application Publication
(10) Pub. No.: US 2009/0159566 A1
(43) Pub. Date: Jun. 25, 2009

(54) METHOD AND APPARATUS FOR CONTROLLING TEMPERATURE OF A SUBSTRATE

(75) Inventors: Paul L. Brillhart, Pleasanton, CA (US); Richard Charles Fovell, San Jose, CA (US); Hamid Tavassoli, Santa Clara, CA (US); Xiaoping Zhou, San Jose, CA (US); Douglas A. Buchberger, JR., Livermore, CA (US); Kallol Bera, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/340,156

(22) Filed: Dec. 19, 2008

Related U.S. Application Data
(60) Provisional application No. 61/016,000, filed on Dec. 21, 2007.

(51) Int. Cl. H01L 21/306; C23C 16/513; C23C 14/22; C23C 14/34

(52) U.S. Cl. 216/58; 427/569; 427/523; 204/192.1; 118/728; 204/298.02; 156/345.52

(57) ABSTRACT

A pedestal assembly and method for controlling temperature of a substrate during processing is provided. In one embodiment, method for controlling a substrate temperature during processing includes placing a substrate on a substrate pedestal assembly in a vacuum processing chamber, controlling a temperature of the substrate pedestal assembly by flowing a heat transfer fluid through a radial flowpath within the substrate pedestal assembly, the radial flowpath including both radially inward and radially outward portions, and plasma processing the substrate on the temperature controlled substrate pedestal assembly. In another embodiment, plasma processing may be at least one of a plasma treatment, a chemical vapor deposition process, a physical vapor deposition process, an ion implantation process or an etch process, among others.

### CROSS-REFERENCE TO RELATED APPLICATION

This application claims benefit of U.S. Provisional Application Ser. No. 61/016,000 filed Dec. 21, 2007 (Attorney Docket No. APPM/12975L), which is incorporated by reference in its entirety.

### BACKGROUND OF THE INVENTION

1. Field of the Invention

Embodiments of the present invention generally relate to semiconductor substrate processing systems. More specifically, the invention relates to a method and apparatus for controlling temperature of a substrate in a semiconductor substrate processing system.

2. Description of the Related Art

In manufacture of integrated circuits, precise control of various process parameters is required for achieving consistent results within a substrate, as well as the results that are reproducible from substrate to substrate. As the geometry limits of the structures for forming semiconductor devices are pushed against technology limits, tighter tolerances and precise process control are critical to fabrication success. However, with shrinking geometries, precise critical dimension and etch process control has become increasingly difficult. During processing, changes in the temperature and/or temperature gradients across the substrate may be detrimental to etch rate and uniformity, material deposition, step coverage, feature taper angles, and other parameters of semiconductor devices.

A substrate support pedestal is predominantly utilized to control the temperature of a substrate during processing, generally through control of backside gas distribution and the heating and cooling of the pedestal itself. Although conventional substrate pedestals have proven to be robust performers at larger critical dimension, existing techniques for controlling the substrate temperature distribution across the diameter of the substrate must be improved in order to enable fabrication of next generation, submicron structures, such as those having critical dimensions of about 55 nm and beyond.

Therefore, there is a need in the art for an improved method and apparatus for controlling temperature of a substrate during processing the substrate in a semiconductor substrate processing apparatus.

### SUMMARY OF THE INVENTION

The present invention generally is a method and apparatus for controlling temperature of a substrate during processing in a semiconductor substrate processing apparatus. The method and apparatus enhances temperature control across the diameter of a substrate, and may be utilized in etch, deposition, implant, and thermal processing systems, among other applications where the control of the temperature profile of a workpiece is desirable.

In one embodiment, a method for controlling a substrate temperature during processing includes placing a substrate on a substrate pedestal assembly in a vacuum processing chamber, controlling a temperature of the substrate pedestal assembly by flowing a heat transfer fluid through a radial flowpath within the substrate pedestal assembly, the radial flowpath including both radially inward and radially outward portions, and plasma processing the substrate on the temperature controlled substrate pedestal assembly. In another embodiment, plasma processing may be at least one of a plasma treatment, a chemical vapor deposition process, a physical vapor deposition process, an ion implantation process or an etch process, among others.

In another embodiment of the invention, a pedestal assembly is provided that includes a base having an electrostatic chuck secured to a top surface thereof. A cooling flowpath formed in the base, the cooling flowpath configured to direct flow both radially inward and radially outward.

In yet another embodiment of the invention, a pedestal assembly is provided that includes a base having an electrostatic chuck secured to a top surface thereof. A substantially toroidal flowpath formed in the base, the substantially flowpath having an inlet and outlet formed in a bottom surface of the base.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic diagram of an exemplary semiconductor substrate processing apparatus comprising a substrate pedestal in accordance with one embodiment of the invention;

FIGS. 2A-B are a schematic cross-sectional view and a top view of one embodiment of a substrate pedestal illustrating a cooling flowpath;

FIG. 3 is a cross sectional view of the substrate pedestal of FIG. 1;

FIG. 4 is a top view of the substrate pedestal of FIG. 1 illustrating one embodiment of a cover plate disposed on a base plate;

FIG. 5 is a top view of the substrate pedestal of FIG. 1 with the cover plate removed to expose the top of the base plate;

FIG. 6 is a bottom view of the substrate pedestal of FIG. 1;

FIGS. 6A-B are partial sectional and an enlarged bottom views of one embodiment of a flow director;

FIG. 7 is a bottom view the base plate;

FIG. 8 is a top view of one embodiment of a channel separator plate;

FIG. 9 is a bottom view of the channel separator plate;

FIG. 10 is a bottom isometric view of the channel separator plate

FIG. 11 is a partial sectional view of the substrate pedestal of FIG. 1;

FIG. 12 is another partial sectional view of the substrate pedestal of FIG. 1 illustrating a connection ports for the cooling inlet and outlet;

FIG. 13 is an exploded isometric view of another embodiment of a base assembly;

FIGS. 14-16 are bottom, side and top view of one embodiment of a channel separator plate of the base assembly of FIG. 13;

FIG. 17 is a bottom isometric view of one embodiment of a inlet manifold cage;

FIG. 18 is a partial side sectional view of the channel separator plate and inlet manifold cage;

FIGS. 19-21 are bottom, side and top view of one embodiment of a bottom cover plate of the base assembly of FIG. 13;

FIG. 22 is a partial side cutaway isometric view of the base assembly of FIG. 13; and

FIGS. 23-26 are alternative bottom views of a base plate of the base assembly of FIG. 13.

To facilitate understanding, identical reference numerals have been used, where possible, to designate identical elements that are common to the figures. It is also contemplated that elements and features of one embodiment may be beneficially incorporated on other embodiments without further recitation.

### DETAILED DESCRIPTION

The present invention generally is a method and apparatus for controlling temperature of a substrate during processing. Although invention is illustratively described in a semiconductor substrate processing apparatus, such as, e.g., a processing reactor (or module) of a CENTURA® integrated semiconductor wafer processing system, available from Applied Materials, Inc. of Santa Clara, Calif., the invention may be utilized in other processing systems, including etch, deposition, implant and thermal processing, or in other application where control of the temperature profile of a substrate or other workpiece is desirable.

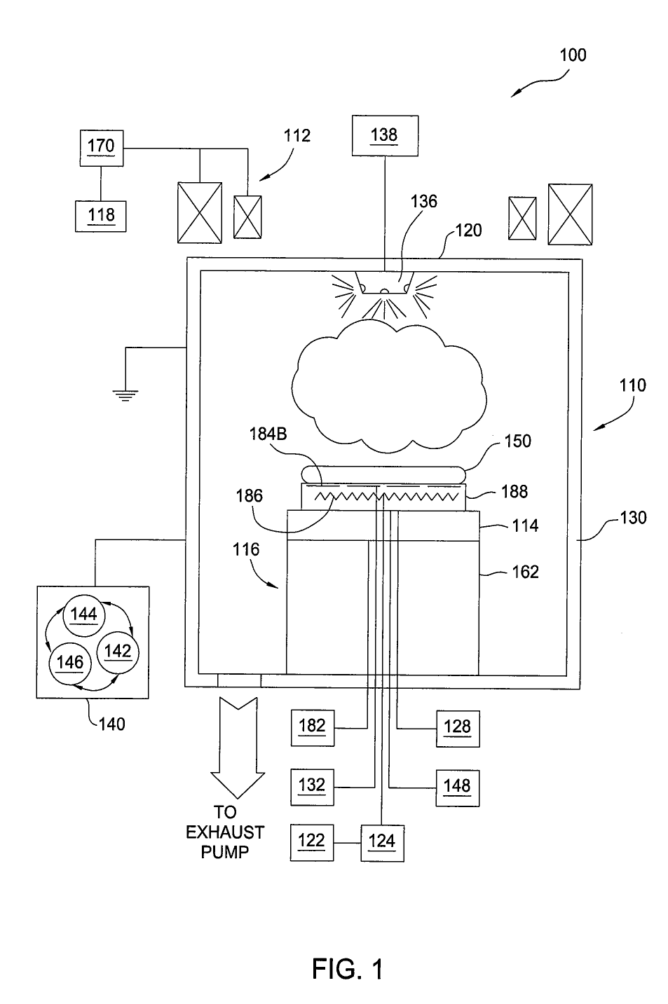

FIG. 1 depicts a schematic diagram of an exemplary etch reactor 100 having one embodiment of a substrate pedestal assembly 116 having an internal radial coolant flowpath. The particular embodiment of the etch reactor 100 shown herein is provided for illustrative purposes and should not be used to limit the scope of the invention.

Etch reactor 100 generally includes a process chamber 110, a gas panel 138 and a controller 140. The process chamber 110 includes a conductive body (wall) 130 and a ceiling 120 that enclose a process volume. Process gasses from the gas panel 138 are provided to the process volume of the chamber 110 through a showerhead or one or more nozzles 136.

The controller 140 includes a central processing unit (CPU) 144, a memory 142, and support circuits 146. The controller 140 is coupled to and controls components of the etch reactor 100, processes performed in the chamber 110, as well as may facilitate an optional data exchange with databases of an integrated circuit fab.

In the depicted embodiment, the ceiling 120 is a substantially flat dielectric member. Other embodiments of the process chamber 110 may have other types of ceilings, e.g., a dome-shaped ceiling. Above the ceiling 120 is disposed an antenna 112 comprising one or more inductive coil elements (two co-axial coil elements are illustratively shown). The antenna 112 is coupled, through a first matching network 170, to a radio-frequency (RF) plasma power source 118.

In one embodiment, the substrate pedestal assembly 116 includes a mount assembly 162, a base assembly 114 and an electrostatic chuck 188. The mounting assembly 162 couples the base assembly 114 to the process chamber 110.

The electrostatic chuck 188 is generally formed from ceramic or similar dielectric material and comprises at least one clamping electrode 186 controlled using a power supply 128. In a further embodiment, the electrostatic chuck 188 may comprise at least one RF electrode (not shown) coupled, through a second matching network 124, to a power source 122 of substrate bias. The electrostatic chuck 188 may optionally comprise one or more substrate heaters. In one embodiment, two concentric and independently controllable resistive heaters, shown as concentric heaters 184A, 184B, are utilized to control the edge to center temperature profile of the substrate 150.

The electrostatic chuck 188 may further comprise a plurality of gas passages (not shown), such as grooves, that are formed in a substrate supporting surface of the chuck and fluidly coupled to a source 148 of a heat transfer (or backside) gas. In operation, the backside gas (e.g., helium (He)) is provided at controlled pressure into the gas passages to enhance the heat transfer between the electrostatic chuck 188 and the substrate 150. Conventionally, at least the substrate supporting surface of the electrostatic chuck is provided with a coating resistant to the chemistries and temperatures used during processing the substrates.

The base assembly 114 is generally formed from aluminum or other metallic material. The base assembly 114 includes one or more cooling passages that are coupled to a source 182 of a heating or cooling fluid. A heat transfer fluid, which may be at least one gas such as Freon, Helium or Nitrogen, among others, or a liquid such as water or oil, among others, is provided by the source 182 through the passages to control the temperature of the base assembly 114, thereby heating or cooling the base assembly 114, thereby controlling, in part, the temperature of a substrate 150 disposed on the base assembly 114 during processing.

Temperature of the pedestal assembly 116, and hence the substrate 150, is monitored using a plurality of sensors (not shown in FIG. 1). Routing of the sensors through the pedestal assembly 116 is further described below. The temperature sensors, such as a fiber optic temperature sensor, are coupled to the controller 140 to provide a metric indicative of the temperature profile of the pedestal assembly 116.

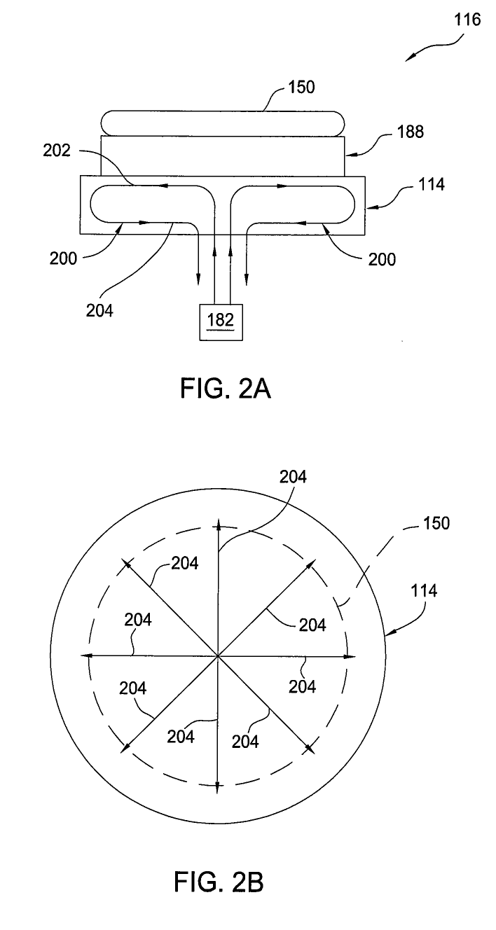

FIGS. 2A-B are a schematic cross-sectional view and a top view of one embodiment of a substrate pedestal assembly 116 illustrating a cooling flowpath 200 configured to provide uniform temperature control of the substrate pedestal assembly 116. The substrate pedestal assembly 116 includes an electrostatic chuck 188 disposed on a base assembly 114. The flowpath 200 may be routed through one or more passages formed through the base assembly 114. The flowpath 200 has a generally radial orientation through the base assembly 114. Although the flowpath 200 is shown in FIG. 2A has having a center inlet such that the heat transfer fluid provided by the source 182 flows radially outward, it is contemplated that the direction of flow may be reversed.

In one embodiment, the flowpath 200 includes a first radial path 202 and a second radial path 204. The first and second radial paths 202, 204 are configured to direct flow of the heat transfer fluid in substantially opposite directions. The base assembly 114 is generally larger in diameter than the electrostatic chuck 188 such that the first and second radial paths 202, 204 extend radially beyond the outer diameter of the chuck 188 and substrate 150 to provide good temperature control at the edge of the substrate.

In the embodiment depicted in FIGS. 2A-B, the first radial path 202 is adjacent the surface of the base assembly 114 that contacts the electrostatic chuck 188, while the second radial path 204 is dispose below the first radial path 202. In one embodiment the flowpath 200 has a mushroom configuration, e.g., is substantially a torus. The toroidal shape of the flowpath 200 may be comprised of a plurality of individual radial passages, or a single passage.

The toroidal shape significantly reduces the length of the flowpath utilized in conventional bases. For examples, in a comparably sized base suitable for processing 300 mm substrates, the configuration of a flowpath of one embodiment of the invention reduces the flowpath length from approximately 72 inches in bases of conventional substrate supports to about 6 inches. This reduction in length greatly reduces the temperature drop between the inlet and outlet of the cooling passages, thereby significantly reducing temperature gradients in the substrate support pedestal. In one embodiment, the temperature delta between the inlet and outlet of the cooling passages is about 0.1 to about 1.0 as compared to about 7 to about 17 degrees Celsius in conventional substrate supports. The fluid inlet temperature range may be between (−)100 degrees Celsius to about (+)200 degrees Celsius, such as between (−)30 to about (+)85 degrees Celsius. This arrangement of the radial flowpath also has a significant reduction in the flow resistance, thereby allowing greater fluid flow and higher heat transfer rates at a selected operational pressure.

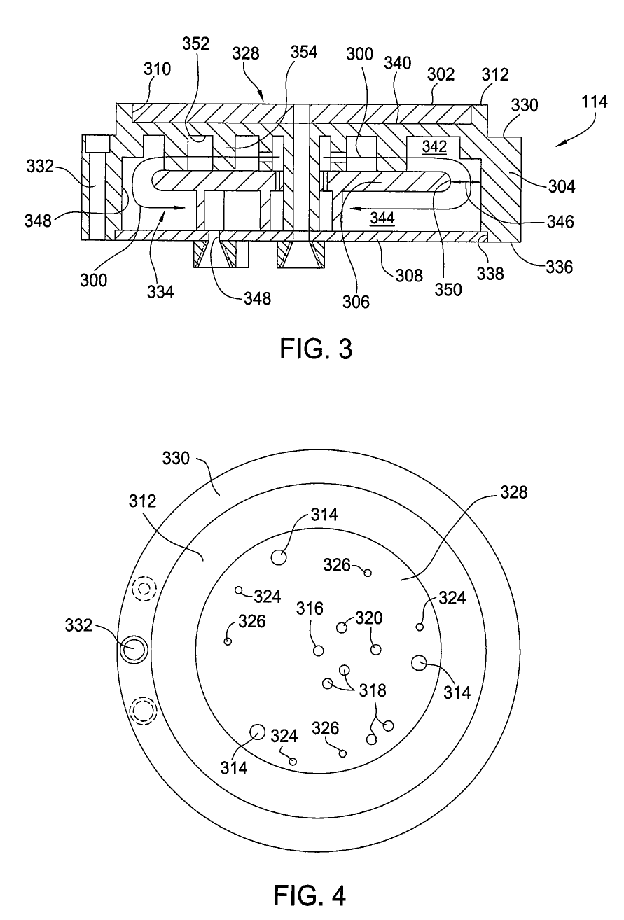

FIG. 3 is a cross sectional view of the base assembly 114 of FIG. 1. In one embodiment, the base assembly 114 includes an internal coolant flowpath 300 that is substantially radial in orientation. In another embodiment, the flowpath 300 may be configured as described with reference to the flowpath 200.

In one embodiment, the base assembly 114 includes a top cover plate 302, a base plate 304, a channel separator plate 306 and a bottom cover plate 308. The plates 302, 304, 306, 308 are generally fabricated from a good thermal conductor, for example a metal, such as stainless steel or aluminum.

The top cover plate 302 is disposed in a recess 310 formed in a top 312 of the base plate 304. The depth of the recess 310 may be selected such that a top surface 328 of the top cover plate 302 is substantially coplanar with the top 312 of the base plate 304. The electrostatic chuck 188 (not shown in FIG. 3) is supported at least one the top surface 328 of the top cover plate 302.

Referring additionally to the top view of the base assembly 114 depicted in FIG. 4, the top cover plate 302 includes a plurality of apertures. The apertures are utilized for lift pins and routing of various heaters, sensor, gas and power utilities through the base assembly 114 to the electrostatic chuck 188. In the embodiment depicted in FIG. 4, apertures 314 are provided for lift pins, aperture 316 is provided for chuck power utilities, apertures 318 are provided for heater elements, apertures 320 are provide for temperature sensors, and apertures 324, 326 are provide for delivery of a heat transfer gas between the top cover plate 302 and the electrostatic chuck 188. The same reference numerals may be used to identity apertures in other components of the base assembly 114 utilized for routing the same.

The base plate 304 includes a step 330 through which a plurality of mounting holes 332 are formed through. The mounting holes 332, one of which is shown for sake of clarity, are generally arranged on a bolt circle on the step 330. The step 330 is disposed outward and below the top 312 of the base plate 302, and therefore, is also beyond the edge of the substrate 150.

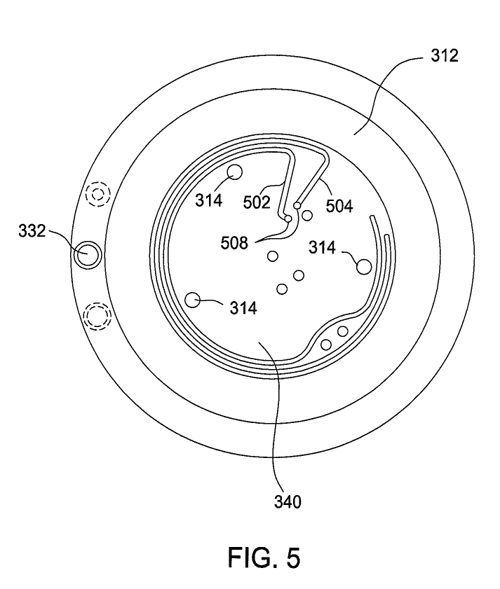

FIG. 5 is a top view of the substrate pedestal 114 with the cover plate 302 removed to expose a recessed surface 340 of the base plate 304. The recessed surface 340 includes a plurality of cooling channels formed therein. In the embodiment depicted in FIG. 5, an inner cooling channel 502 and an outer cooling channel 504 are provided. Helium, or other heat transfer gas or fluid, is provided to the cooling channels 502, 504 through respective inlets 506, 508. The heat transfer gas is distributed through the channels 502, 504 to the plurality of apertures 324, 326 in the cover plate 302 (shown in FIG. 4), through which the heat transfer gas is distributed between the electrostatic chuck 188 and base assembly 114. The temperature of the fluids in the channels 502, 504 may have their temperature independently regulated to assist in providing center to edge substrate temperature control.

Referring back to FIG. 3, the base plate 304 includes a cavity 334 formed in a bottom 336 of base plate 304. The bottom cover plate 308 is sealingly coupled to the bottom 336 of the base plate 304 to seal the channel separator plate 306 within the cavity 334. In one embodiment, the bottom cover plate 308 is disposed a step 338 formed in the bottom 336 of the base plate 304, and sealed to the base plate 304 by a continuous weld or other suitable technique.

The channel separator plate 306 bifurcates the cavity 334 into two disc-shaped plenums 342, 344. The plenums 342, 344 are vertically stacked and fluidly coupled through a gap 346 defined between an outer sidewall 346 of the cavity 344 and an outside edge of the channel separator plate 306. In the embodiment depicted in FIG. 3, the radial coolant flowpath is defined through the upper plenum 342 into the lower plenum 344 though the gap 348. It is also contemplated that the direction of flow through the flowpath may be reversed.

In one embodiment, the channel separator plate 306 maintained in a spaced-part relation from a top wall 352 of the cavity 334 by a plurality of spacers 354. The spacers 354 are part of the base plate 304. At least some of the spacers 354 may have a radial orientation such that the flow through the upper plenum 342 is directed radially.

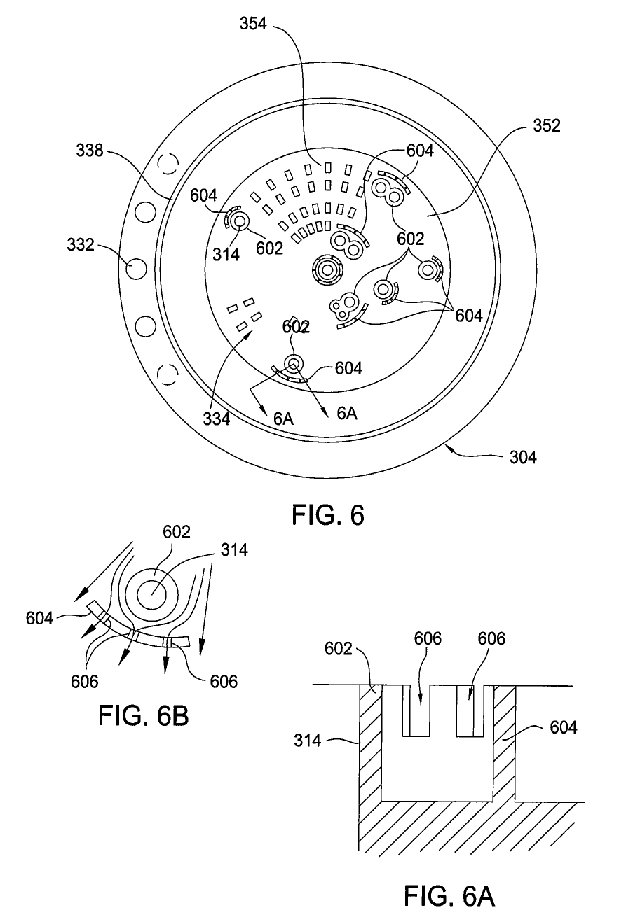

FIG. 6 depicts a bottom view of the base plate 304 illustrating the spacers 354 projecting form the top wall 352. Only a small number of spacers 354 are shown in FIG. 6 for the sake of clarity, as the spacers 354 are distributed 360 degrees around the centerline of the base plate 304. At least some of the spacers 354 bridge the space between the top wall 352 and the channel separator plate 306. The number, orientation, distribution and size of the spacers 354 may be selected to provide a desired profile of heat transfer from the base plate 304 to the fluid disposed in the upper plenum 342. In the embodiment depicted in FIG. 6, the spacers 354 are elongated and have a major axis aligned with the radial flow direction. The spacers 354 may also be staggered so that flow passing between two adjacent spacers 354 positioned at the same radius from the centerline of the base plate 304 will be directed towards the next outward spacer 354, thereby causing some lateral movement and mixing of the cooling fluid as it mores outward towards the gap 348.

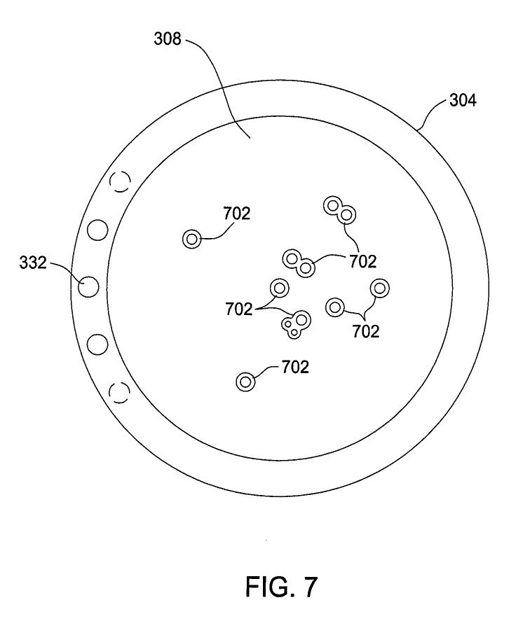

Additionally shown in FIG. 6 are a plurality of bosses 602 through which the various apertures 314, 316, 318, 320, 322, 324, 326 extend. The bosses 602 provide a barrier between the apertures and the plenum 342. The bosses 602 align with bosses 702 (shown in FIG. 7) present on the outside of the base cover plate 308 to facilitate routing of utilities, sensors, heaters, fluids, and the like through the pedestal assembly 116. The joint between the bottom cover plate 308 and base plate 304 may be brazed or sealed in another suitable fashion to prevent entry of fluids into the apertures.

Referring additionally to the detailed views of FIGS. 6A-B, a flow director 604 may be provided on the downstream side of each of the bosses 604 to promote wrapping of the heat transfer fluid flowing through the plenum 342 around the backside of the boss. In one embodiment, the flow director 604 has an orientation substantially orthogonal to the orientation of the spacers 354. The flow director 604 may additionally include one or more slots 606 that allow the fluid directed between the boss 602 and director 604 to escape, thus maintaining flow between the boss 602 and director 604, as shown by the arrows depicted in FIG. 6A. Alternatively, the flow director 604 may not bridge the space between the channel separator plate 306 and the top wall 352 of the base plate 304, thereby functioning as a weir such that a portion of the fluid between the boss 602 and director 604 may escape over the director 604. The wrapping of the fluid promotes good heat transfer from the bosses 604, thus compensating for the low heat transfer rate through the voids of the apertures.

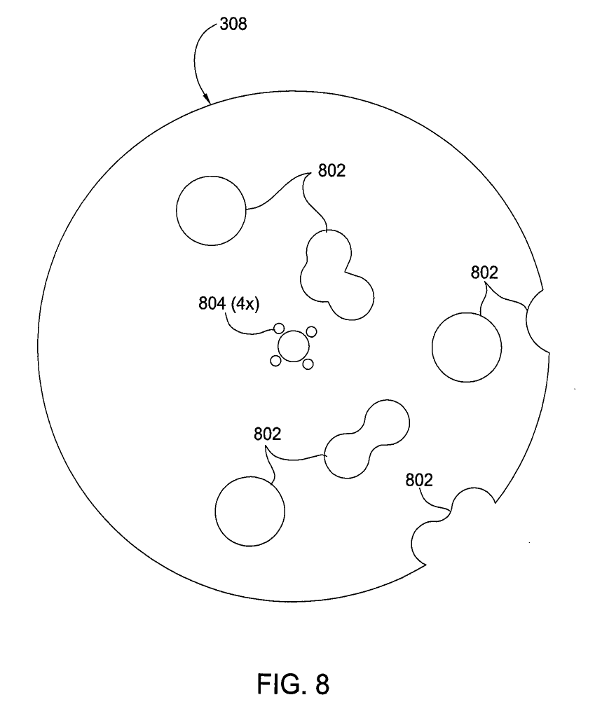

FIG. 8 is a top view of one embodiment of the channel separator plate 306. The channel separator plate 306 includes a plurality of holes 802 through with the bosses 602 of the base plate 304 extend. The channel separator plate 306 also includes one or more inlet holes 804, which allow entry of the coolant fluid into the cavity 334, as further described below.

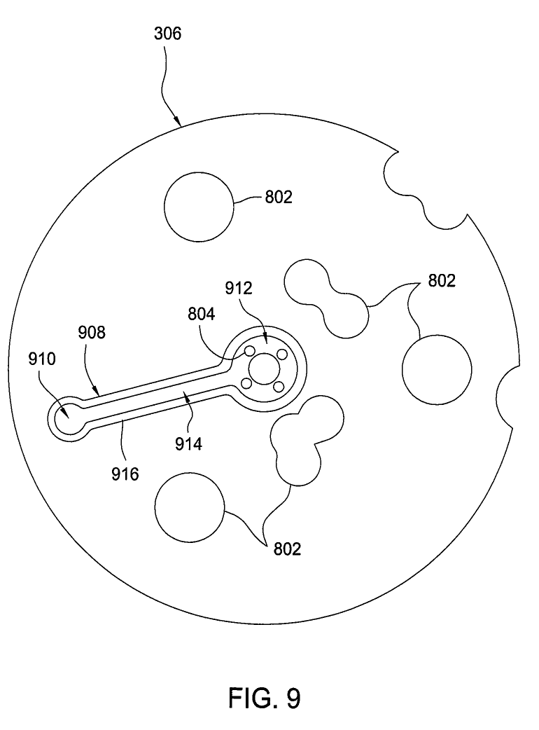

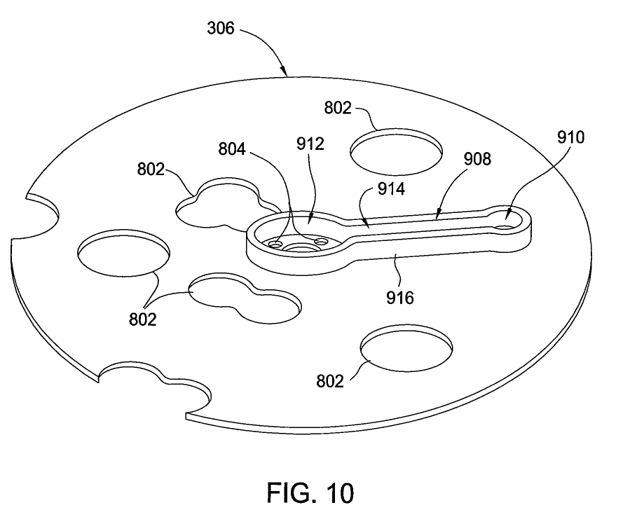

FIGS. 9-10 are a bottom and bottom isometric views of the channel separator plate 306. The channel separator plate 306 includes a lateral feed 908 for providing heat transfer fluid to the inlet holes 804. The lateral feed 908 allows the heat transfer fluid inlet of the pedestal assembly 116 to be offset from the center of the pedestal, thereby allowing more efficient space utilization for routing electrical utilities, lift pins, gas channels and the like. In the embodiment depicted in FIG. 9, the lateral feed 908 is defined by a wall 916 that projects from the bottom of the channel separator plate 306. The wall 916 has a generally hollow, dog-bone shape, surrounding an outer plenum 910 at a first end of the lateral feed 908, an inner plenum 912 at a second end of the lateral feed 908, and a channel fluidly coupling the plenums 910, 912. The outer plenum 910 is generally positioned outward from the center of the channel separator plate 306. The outer plenum 910 is positioned to align with a fluid inlet hole 398 formed in the bottom cover plate 308 (as shown in FIGS. 3 and 12). The inner plenum 912 is generally positioned at the center of the channel separator plate 306. The portion of the wall 916 surrounding the inner plenum 912 is wide enough to surround the inlet holes 804 so that fluid from the lateral feed 908 is directed through holes 804 in the channel separator plate 306 and into a center distribution plenum defined on the upper side of the channel separator plate 306.

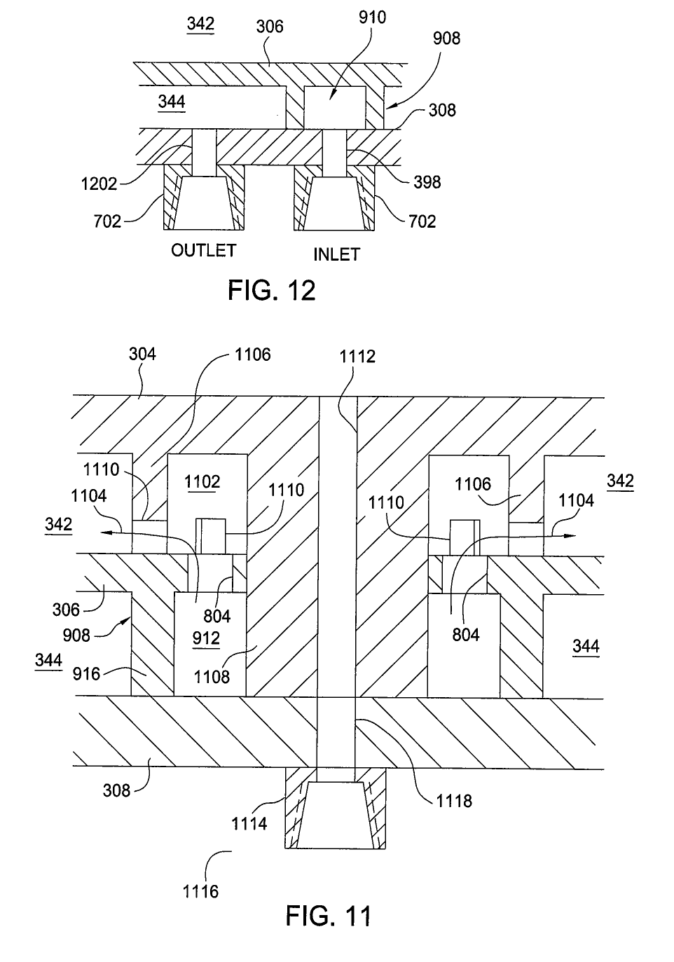

FIG. 11 is an enlarged sectional view of the base assembly 114 illustrating one embodiment a center distribution plenum 1102. The center distribution plenum 1102 is bounded by the channel separator plate 306 on the bottom and the base plate 304 on the top. A wall 1106 extends downward from the base plate 304 to provide an outer boundary of the center distribution plenum 1102. The wall 1106 is positioned outward of the holes 804 so as to allow the holes 804 to provide a fluid passage between the plenums 912, 1102. The wall 1106 is configured to allow fluid to escape radially from the center distribution plenum 1102 into the upper plenum 342, as shown by arrows 1104.

In one embodiment, the wall 1106 includes one or more passages 1110, such as holes or slots, through which the fluid may escape into the upper plenum 342 from the center distribution plenum 1102. In one embodiment, the passages 1110 are through holes. In the embodiment depicted in FIG. 11, the wall 1106 has a generally cylindrical shape, having passages 1110 formed in a distal end. The passages 1110 may be spaced equidistantly along the wall 1106. Alternatively, the one or more passages 1110 may be configured as a continuous weir that allows the flow of fluid to be directed equally in all radial directions. Optionally, the number and spacing of the passages 1110 may be selected to direct more flow to one region of the upper plenum 342 relative to another region of the upper plenum 342, if desired.

Also shown in FIG. 11, the base plate 306 includes a center boss 1108 which isolates a center passage 1112 from the fluids in the plenums 912, 1102. The center passage 1112 is aligned with the aperture 316 formed through the top cover plate 302 and a hole 1118 formed through the bottom cover plate 308. The passage 1112, aperture 316 and hole 1118 facilitate routing of utilities to the electrostatic chuck 118 through the pedestal assembly 116. The joint between the bottom cover plate 308 and boss 1108 may be brazed or sealed in another suitable fashion to prevent entry of fluids into the passages. One of the bosses 702 of the bottom cover plate 308, shown as boss 1114 in FIG. 11, has a port 1116 formed therein to facilitate coupling of the utility conduit. The other bosses 702 are similarly configured.

The fluid outlet of the flowpath through the pedestal assembly 116 is shown in the partial sectional view of FIG. 12. A fluid outlet hole 1202 is formed through the bottom cover plate 308 to drain the lower plenum 344. The outlet hole 1202 is generally positioned near the inlet hole 398. Two of the bosses 702 formed on the bottom cover plate 308, shown as inlet boss 1204 and outlet boss 1206 in FIG. 12, are utilized to provide fluid connection to the flowpath 300 through the holes 398, 1202. In one embodiment, the boss 1204 is coupled to the heat transfer fluid source 182 while the boss 1206 is coupled to a drain or recirculated back through the fluid source 182. The pressure, flow rate, temperature, density and composition of the heat transfer medium of cooling fluid provided through the flowpath 300 provides enhanced control of the heat transfer profile through the pedestal assembly 116. Moreover, as the density, pressure and flow rate of fluid in the flowpath 300 may be controlled in-situ during processing of substrate 150, the temperature control of the substrate 150 may be changed during processing to further enhance processing performance.

In operation, a substrate 150 is provided on the pedestal assembly 116. Power is provide to the electrostatic chuck 188 to secure the substrate. Power is provided to the heaters within the electrostatic chuck 188 to provide control of the lateral temperature provide of the substrate 150. Coolant fluid, which may be liquid and/or gas, such as Freon, is provided through the radial cooling path defined in the base assembly 114 to enable precise temperature control of the substrate.

In one embodiment, coolant is provided to the center distribution plenum 1102 from which the coolant is distributed radially through the one or more passages 1110 into the disk shaped upper plenum 342. Flow directors 604 are utilized to promote wrapping of the heat transfer fluid flowing through the upper plenum 342 around the various bosses 604 extending through the plenum 342. The coolant then flows from the upper 342 through gap 348 into the lower disk shaped platen 344, from which the coolant is ultimately removed. The radial configuration of the coolant flowpath, along with the cross flow orientation, reduces coolant path length and pressure drop, beneficially contribute to the enhanced cooling uniformity of the pedestal assembly 116, thereby enabling improved process control within the reactor 100.

For example, the above mentioned substrate temperature control may be beneficially employed during an etch process wherein a plasma is formed within the reactor 100 from gases provided from the gas panel 138. Other substrate fabrication processes, such as those mentioned above and performed in a vacuum chamber and/or requiring precise temperate control may also benefit from the use of the temperature control methods and apparatuses described therein.

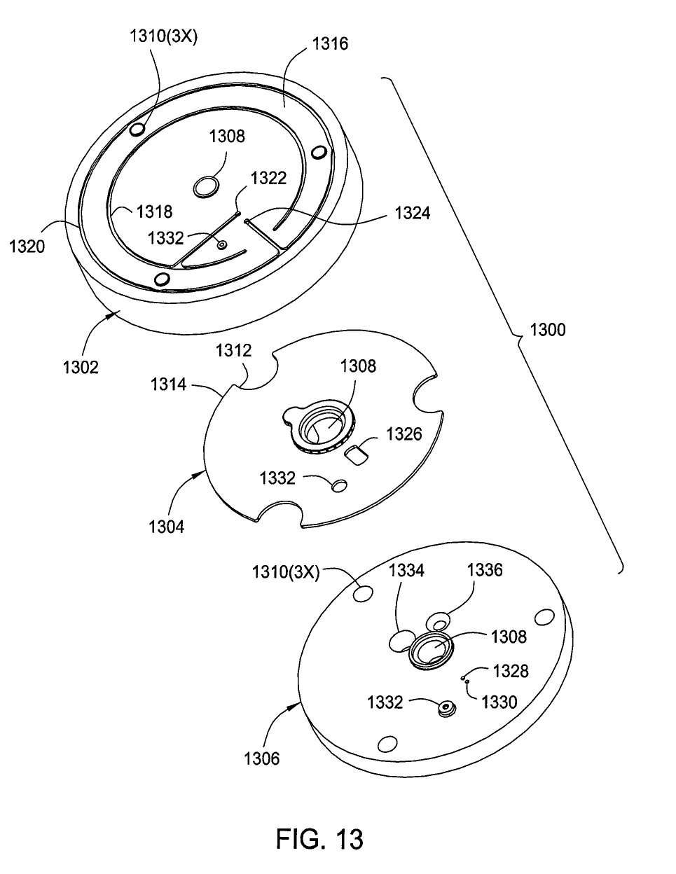

FIG. 13 is an exploded isometric view of another embodiment of a base assembly 1300 through which heat transfer fluid flows from an upper disc-shaped plenum into a lower disc-shaped plenum from which the fluid is ultimately removed. The base assembly 1300 includes a base plate 1302, a channel separate plate 1304 and a bottom cover plate 1306. The base plate 1302 and the bottom cover plate 1306 are sealingly coupled together capturing the channel separator plate 1304 therebetween such that coolant fluid introduced between the channel separator plate and the base plate flows outward and over an outer diameter 1314 of the channel separator plate 1304 into a bottom plenum defined between the channel separator plate 1304 and the bottom cover plate 1306. The base plate 1302, channel separator plate 1304 and the bottom cover plate 1306 all include a central aperture 1308 which provides a conduit for routing power and other utilities to the electrostatic chuck 188 (shown in FIG. 1) which is coupled to a top 1316 of the base plate 1302.

The base plate 1302 and the bottom cover plate 1306 also include a plurality of lift pin holes 1310. The channel separator plate 1304 includes a plurality of notches 1312 formed in the outer diameter 1314 which are aligned with the lift pin holes 1310 such that the channel separator plate 1304 does not interfere with the operation of the lift pins.

The top 1316 of the base plate 1302 additionally includes an inner channel 1318 and an outer cooling channel 1320. The inner channel 1318 is fed through an inlet 1322 formed through the base plate 1302. The outer channel 1320 is fed fluid through an inlet 1324 formed through the base plate 1302. Cooling fluid feeds 1328, 1330 are provided in the bottom cover plate 1306 and aligned with the inlets 1320, 1322 to allow a fluid, such as He, Nitrogen or other fluids, to be routed through the base assembly to the cooling channels 1318, 1322 to enhance heat transfer between the assembly 1300 and the electrostatic chuck 118. An aperture 1326 is provided in the channel separator plate 1304 to facilitate coupling of the cooling feeds 1328, 1330 to the inlets 1322, 1324.

A passage 1332 is also provided through the base plate 1302, channel separator plate 1304 and bottom cover plate 1306 to allow passage of a thermal couple. The bottom cover plate 1306 additionally includes a pair of apertures 1334, 1336 to facilitate the flow of cooling fluid into and out of the base assembly 1300 as further described below.

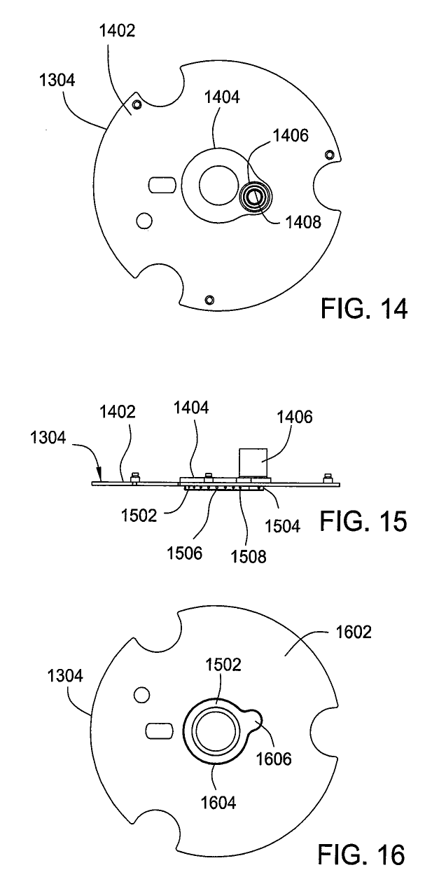

FIGS. 14-16 are bottom, top and side views of the channel separator plate 1304. The channel separator plate 1304 includes a bottom 1402 and a top 1602. A first boss 1404 extends from the bottom 1402 such that a recess is formed in the top 1602 of the channel separator plate 1304. The recess formed in the first boss 1404 accepts a portion of an inlet manifold cage 1502 which extends from the top 1602 of the channel separator plate 1304. A second boss 1406 extends from the first boss 1404 from the bottom 1402 of the channel separator plate 1304. The second boss 1406 includes a passage 1408 formed through the channel separator plate 1304. The passage 1408 allows fluid entering the base assembly 1300 to flow through the inlet manifold cage 1502 and into the upper plenum defined between the channel separator plate 1304 and the base plate 1302.

The inlet manifold cage 1502 includes sides 1504 and a top 1506. A plurality of windows 1508 are formed through the sides 1504 of the inlet manifold cage 1502 to facilitate the flow of fluid entering the base assembly 1300 through the passage 1408 to the upper plenum defined between the channel separator plate 1304 and the base plate 1302. The windows 1508 may be holes, slot or other features suitable for allowing fluid to flow therethrough.

The inlet manifold cage 1502 includes a ring 1604 which circumscribes the center aperture 1308. An extension 1606 is formed on the outer diameter of the ring 1604 and is aligned with the passage 1408 formed through the second boss 1406 such that fluid directed through the second boss 1406 enters the volume defined within the inlet manifold cage 1502.

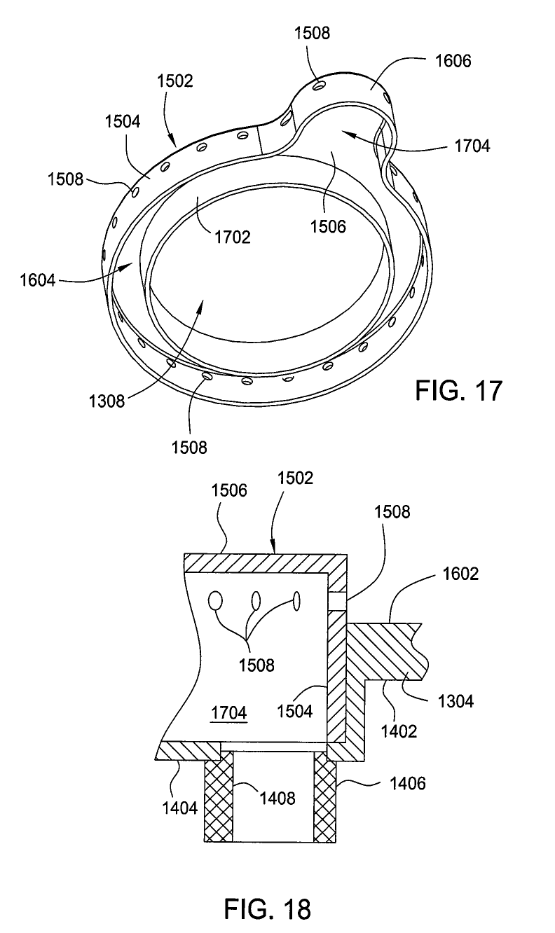

FIG. 17 is a bottom isometric view of one embodiment of the inlet manifold cage 1502. The inlet manifold cage 1502 includes an annular inner wall 1702 which is circumscribed by the side 1504. The inner wall 1702, the side 1504 and the top 1506 of the inlet manifold cage 1504 define a fluid passage 1704 within the manifold cage 1502.

FIG. 18 is a partial side sectional view of the channel separator plate 1304 and the inlet manifold cage 1502. As depicted in the embodiment of FIG. 18, the inlet manifold cage 1502 sits partially within the recess formed in the first boss 1404. The windows 1508 are arranged along the sides 1504 of the inlet manifold cage 1502 proximate the top 1506, such that the windows 1508 are positioned to provide fluid to the top 1602 of the channel separator plate 1304. Thus, fluid entering the fluid passage 1704 through the passage 1408 defined through the boss 1406 can readily flow into the upper plenum in a direction radially outward from the sides 1504.

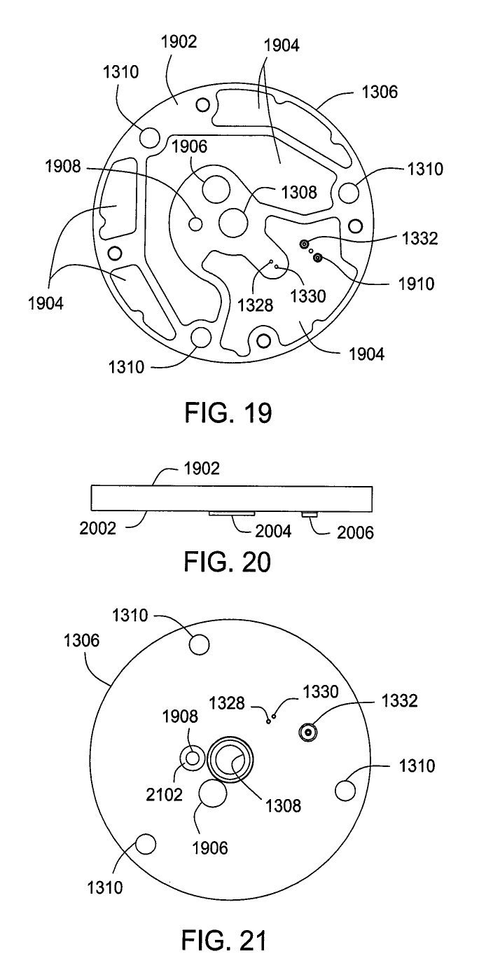

FIGS. 19-21 are bottom, side and top views of one embodiment of the bottom cover plate 1306. A bottom 1902 of the bottom cover plate 1306 includes a plurality of cavities 1904 formed therein to reduce the thermal mass of the bottom cover plate 1306, thereby allowing the assembly 1300 to be heated and cooled more rapidly. The bottom cover plate 1306 additionally includes two holes 1906, 1908 formed therethrough which facilitates routing of the cooling fluid entering and exiting the base assembly 1300. The hole 1906 is sufficiently large enough to accept the boss 1406 extending from the channel separator plate 1304. The hole 1908 facilities draining the lower plenum defined between the bottom cover plate 1306 and the channel separator plate 1304. The hole 1908 may include a counter bore 2158 on the bottom 1902 to facilitate alignment with mating components.

A top 2002 of the bottom cover plate 1306 includes a first boss 2004 and a second boss 2006. The first boss 2004 circumscribes the center aperture 1308. The second boss 2006 has the passage 1332 formed therethrough which is utilized for temperature sensing. The bottom cover plate 1306 may also include a second hole 1910 for accommodating a temperature probe utilized to sense the temperature of the bottom cover plate 1306.

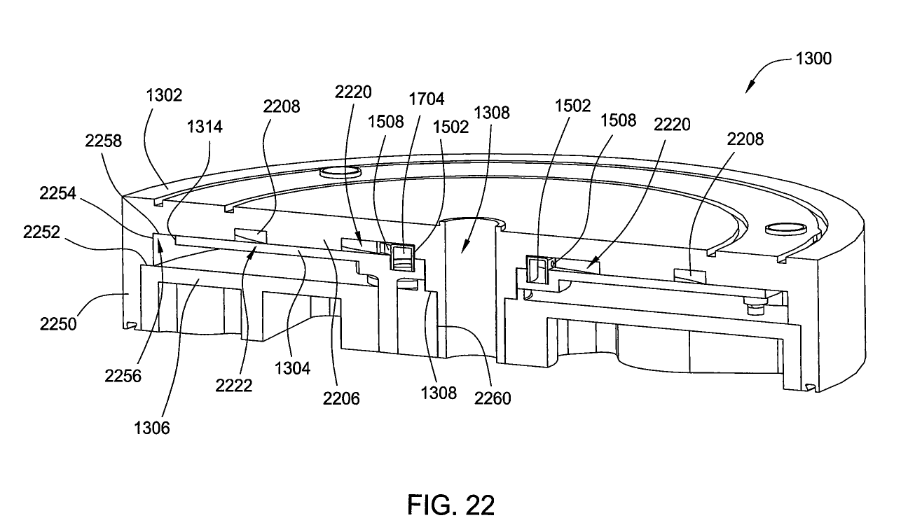

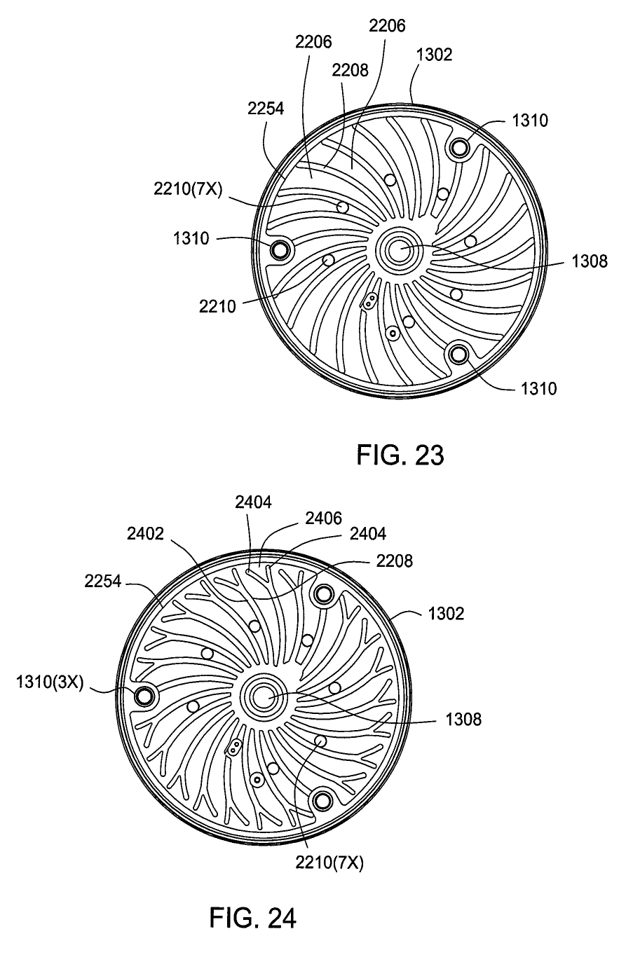

FIG. 22 is a partial cutaway respective view of the face assembly 1300. In the embodiment depicted in FIG. 22, the base plate 1302 includes a lip 2250 extending from the bottom side of the base plate 1302. The lip 2250 has an inside wall 2254 which bounds a pocket 2256 in which the channel separator plate 1304 and the bottom cover plate 1306 are accommodated. The lip 2250 of the bottom cover plate 1306 is sealed to the base plate 1302, for example, by a continuous weld, brazing or other suitable technique, to retain the fluid flowing through the upper and lower plenums within the assembly 1300. The pocket 2256 has a bottom 2258 on which the channel separator plate 1304 is disposed. The bottom 2258 additionally includes a plurality of fins 2206 separating a plurality of channels 2208 formed therein. The fins 2206 and channels 2208 are described in greater detail with reference to FIGS. 23-26 below. The channels 2208 define the majority of an upper plenum 2220 defined between the channel separator plate 1304 and the bottom 2258 of the base plate 1302. Fluid enters the upper plenum 2220 via the windows 1508 formed in the inlet manifold cage 1502. The fluid flows from the inlet manifold cage 1502 through the channels 2208 of the upper plenum 2220 and around the edge 1314 into a gutter 2114 defined between the edge 1314 of the channel separator plate 1304 and the inside wall 2254 of the base plate 1302. Fluid flows from the gutter 2114 into a bottom plenum 2222 and out the hole 1908 formed through the bottom cover plate 1308. Thus, the flow pattern through the plenums 2220, 2222 of the base assembly 1300 is substantially similar to the base assembly 114 described with reference to FIGS. 2A-2B.

The bottom cover plate 1306 is seated on a pair of steps 2252, 2262 formed in the inside wall 2254 and a boss 2260 extending from the bottom 2258 and circumscribing the center aperture 1308. The steps 2252, 2262 maintain the channel separator plate 1304 and the bottom cover plate 1306 in a spaced-apart relation, thus providing ample room for fluid flowing through the lower plenum 2222.

FIGS. 23-26 are alternative bottom views of the base plate 1302 of the base assembly 1300. Common to the embodiments of FIGS. 23-26 is the substantially radial orientation of the channels 2208 and the opposing radial direction of flow through the plenums 2220, 2222.

A plurality of pads 2210 extend from the bottom surface of the base plate 1302. In one embodiment, seven pads are shown extending above the fins 2206. The pads 2210 space the channel separator plate 1304 from the base plate 1302, thereby creating a small gap between the channel separator plate 1304 and the fins 2206 such that minimal heat transfer is directly conducted between the base plate 1302 and the channel separator plate 1304.

In the embodiment depicted in FIG. 23, the channels 2208 have a substantially uniform width and/or sectional area along its radial length outward across the bottom of the base plate 1302. To accommodate the substantially uniform channel width, the fins 2206 are flared, becoming increasingly wider as the fin nears the outside edge of the base plate 1302. The channels 2208 may be linear, curved or have another orientation. In the embodiment depicted in FIG. 23, the channels 2208 are curved such that the fluid flowing through the channels 2208 has a longer residual time within the upper plenum 2220, thereby increasing the heat transfer efficiency.

In the embodiment depicted in FIG. 24, the channels 2208 include a main channel 2402 and a plurality of sub-channels 2404 branching therefrom. In the embodiment depicted in FIG. 24, at least two sub-channels are shown. However, the main channel 2402 may have in excess of three sub-channels 2404, and the sub-channels themselves may be branched into two or more secondary channels (not shown). The sub-channels are separated by an inter-channel fin 2406.

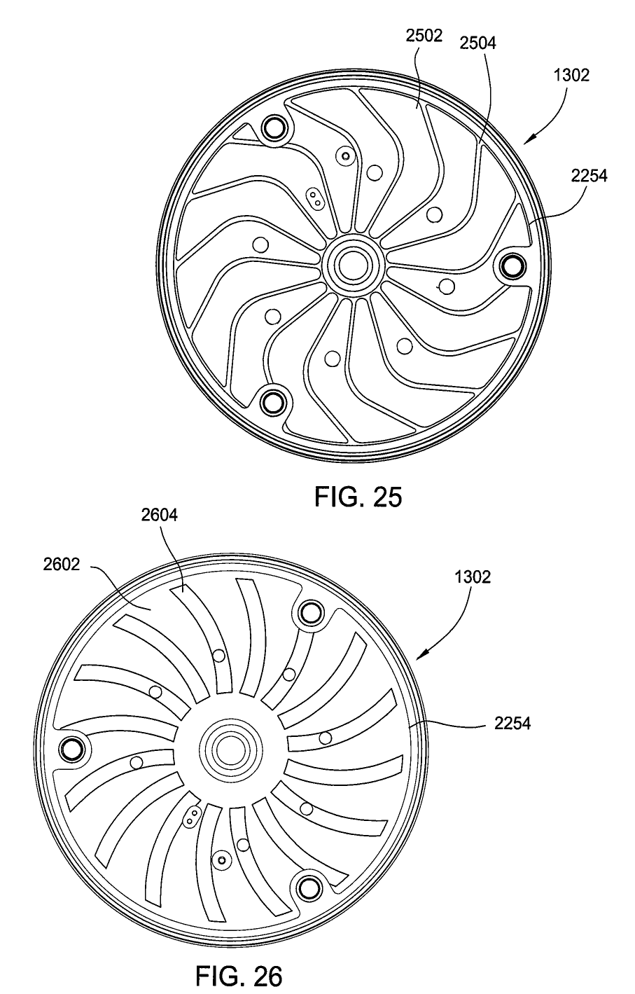

In the embodiment depicted in FIG. 25, a plurality of channels 2502 are shown separated by a plurality of fins 2504. The channels 2502 may have a uniform sectional area and/or width as the channel 2502 extends radially outward. Alternatively, the sectional area and/or width of the channels 2502 may flare as the channel 2502 nears the outer diameter of the base plate 1302. In the embodiment depicted in FIG. 25, the fins 2504 separating the channels 2502 have a substantially boomerang shape, being thicker at the center of the fin 2504 as opposed to each fin end. The boomerang shape allows for a deeply curved channel 2502, thereby substantially increasing the residence time of the fluid in the upper plenum 2220.

In the embodiment depicted in FIG. 26, a plurality of channels 2602 are shown separated by a plurality of fins 2604. Each fin 2604 is substantially uniform in sectional area and/or width as the fin 2604 extends radially outward. Correspondingly, the channels 2602 are flared as they move outward toward the edge of the base plate 1302. The fins 2604 may extend linearly in a radial direction, or they may be curved to increase the residual time of the cooling fluid in the channels 2602 defining the upper plenum 2220.

Thus, a pedestal assembly has been provided that includes a radial coolant flowpath. The radial coolant flowpath through pedestal assembly provides improved temperature control, thereby enabling the temperature profile of the substrate to be controlled.

While the foregoing is directed to embodiments of the present invention, other and further embodiments of the invention may be devised without departing from the basic scope thereof, and the scope thereof is determined by the claims that follow.

What is claimed is:

1. A method for controlling a substrate temperature during processing comprising:
placing a substrate on a substrate pedestal assembly in a vacuum processing chamber;
controlling a temperature of the substrate pedestal assembly by flowing a heat transfer fluid through a radial flowpath within the substrate pedestal assembly, the radial flowpath including both radially inward and radially outward portions; and
plasma processing the substrate on the temperature controlled substrate pedestal assembly.

2. The method of claim 1, wherein plasma processing is at least one of a plasma treatment, a chemical vapor deposition process, a physical vapor deposition process, an ion implantation process or an etch process.

3. The method of claim 1, wherein controlling comprises:
flowing the heat transfer fluid through a substantially toroidal flowpath.

4. The method of claim 1 further comprising:
directing flow of the heat transfer fluid behind obstructions in the flowpath.

5. The method of claim 1, wherein controlling comprises:
flowing the heat transfer fluid into a plenum disposed in the center of the substrate pedestal assembly; and
flowing the heat transfer fluid radially outward from the plenum into a substantially disc-shaped plenum.

6. The method of claim 5, wherein flowing further comprises:
flowing the heat transfer fluid through an annular gap defined radially outward of the first plenum into a second substantially disc-shaped plenum.

7. A pedestal assembly comprising:
an electrostatic chuck; and
a base assembly having the electrostatic chuck secured to a top thereof, the base assembly having a cooling flowpath formed inside the base assembly, the cooling flowpath configured to direct flow radially outward.

8. The pedestal assembly of claim 7, wherein the base assembly comprises:
a base plate having the electrostatic chuck secured thereto; and
a bottom cover plate sealingly coupled to a bottom of the base plate, wherein the cooling flowpath is defined therebetween and includes at least one disk shaped plenum.

9. The pedestal assembly of claim 7, wherein the base assembly comprises:
a base plate having the electrostatic chuck secured thereto;
a bottom cover plate sealingly coupled to a bottom of the base plate;
a channel separator plate disposed between the base plate and the cover plate, wherein the cooling flowpath is at least partially defined between the channel separator plate and the base plate and is at least partially defined between the channel separator plate and the bottom cover plate.

10. The pedestal assembly of claim 9, wherein the base plate comprises:
a plurality of fins having a substantially radial orientation.

11. The pedestal assembly of claim 10, wherein at least one of the fins has a linear orientation.

12. The pedestal assembly of claim 10, wherein at least one of the fins is curved.

13. The pedestal assembly of claim 10, wherein at least one of the channels formed between two of the plurality of fins is branched into at least two sub-channels.

14. The pedestal assembly of claim 9 further comprising:
a manifold cage coupled to the channel separator plate, the inlet manifold cage having a plurality of windows configured to permit a flow of fluid outward through the inlet manifold cage.

15. The pedestal assembly of claim 9, wherein the base assembly comprises:
an upper disk shaped plenum defined between the channel separator plate and the base plate; and
a lower disk shaped plenum defined between the channel separator plate and the bottom cover plate.

16. A pedestal assembly comprising:
an electrostatic chuck;
a base assembly having the electrostatic chuck secured to a top surface thereof; and
a substantially toroidal flowpath formed in the base assembly, the substantially toroidal flowpath having an inlet and outlet formed in a bottom surface of the base assembly.

17. The pedestal assembly of claim 16, wherein the base assembly comprises:
a base plate having the electrostatic chuck secured thereto;
a channel separator plate disposed in a spaced-part relation relative to the base by a plurality of pads, the substantially toroidal flowpath extending over an outer edge of the channel separator plate;
a bottom cover plate sealingly coupled to a bottom of the base plate in a spaced-part relation relative to the channel separator plate.

18. The pedestal assembly of claim 17, wherein the bottom cover plate comprises:
a first hole open to a space defined between the bottom cover plate and the channel separator plate; and
a first hole fluidly coupled to a space defined between the base plate and the channel separator plate.

19. The pedestal assembly of claim 17, wherein the base plate comprises:
a plurality of fins having a substantially radial orientation.

20. The pedestal assembly of claim 17, wherein the base assembly comprises:
a plurality of curved internal fins having a substantially radial orientation.
